(19) United States
(12) Patent Application Publication
(10) Pub. No.: US 2013/0293809 A1
(43) Pub. Date: Nov. 7, 2013

(54) ARRAY SUBSTRATE FOR LIQUID CRYSTAL PANEL, AND LIQUID CRYSTAL PANEL

(71) Applicant: Tatsuro Kuroda, Osaka (JP)

(72) Inventor: Tatsuro Kuroda, Osaka (JP)

(73) Assignee: SHARP KABUSHIKI KAISHA, Osaka (JP)

(21) Appl. No.: 13/979,226

(22) PCT Filed: Jan. 12, 2012
(86) PCT No.: PCT/JP2012/050424

§ 371 Date: Jul. 11, 2013

(30) Foreign Application Priority Data
Jan. 18, 2011 (JP) 2011-007919

(51) Int. Cl. H01L 23/50; G02F 1/1362

(52) U.S. Cl. CPC H01L 23/50; G02F 1/136286
USPC 349/61; 349/106; 257/773

(57) ABSTRACT

Provided is an array substrate for a liquid crystal panel that can suppress disconnection of source wiring lines. An array substrate 11 for a liquid crystal panel, whereupon pixels are arranged in a matrix having rows and columns, is provided with: auxiliary capacitance wiring lines (Cs wiring lines) 35 that extend in the row direction 51, and source wiring lines 34 that extend in the column direction 52. The source wiring lines 34, which are located in an upper layer, have intersection wiring portions 40 at intersection regions 45 of the auxiliary capacitance wiring lines 35 and the source wiring lines 34. The intersection wiring portion 40 includes a first portion 41, which continues to a main body part 34a of the source wiring line 34 and extends in the row direction 51, and a second portion 42, which continues to the first portion 41 and extends in a direction 52 different than the row direction 51.

### TECHNICAL FIELD

The present invention relates to an array substrate for a liquid crystal panel, and a liquid crystal panel, and further relates to a liquid crystal display device provided with a liquid crystal panel.

The present application claims priority to Patent Application No. 2011-7919 filed in Japan on Jan. 18, 2011, which is hereby incorporated by reference in its entirety.

### BACKGROUND ART

Liquid crystal display devices are made of a liquid crystal panel in which liquid crystal is sealed between a pair of transparent substrates, and a backlight arranged on the rear side of the liquid crystal panel. In liquid crystal display devices, images displayed on the liquid crystal panel are visible due to light emitted from the backlight being radiated from the rear side of the liquid crystal panel (Patent Document 1).

FIG. 16 is a perspective view showing a configuration of a liquid crystal panel 1000 shown in Patent Document 1. The liquid crystal panel 1000 shown in FIG. 16 is made of an array substrate (a lower substrate) 110 that includes thin film transistors (TFTs) 140, and a color filter substrate (an upper substrate) 120 that includes a color filter layer 122. A liquid crystal layer 130 is disposed between the array substrate 110 and the color filter substrate 120.

Pixel electrodes 111 are formed on the array substrate 110. Pixel areas 115 are defined by these pixel electrodes 111. Furthermore, gate wiring lines 112 and data wiring lines 114 are formed on the array substrate 110. The TFTs 140 are connected to the gate wiring lines 112 and the data wiring lines 114. The TFTs 140 are arranged adjacent to respective intersections of the gate wiring lines 112 and the data wiring lines 114, and each include a gate electrode 141, a semiconductor layer 142, a source electrode 144, and a drain electrode 146. The drain electrode 146 of each TFT 140 is connected to the pixel electrode 111.

The color filter substrate (the CF substrate) 120 includes the color filter layer 122 having sub-color filter layers 122a, 122b, and 122c of red (R), green (G), and blue (B). The sub-color filter layers 122a, 122b, and 122c are partitioned by a black matrix 123. A common electrode 124 is formed on the liquid crystal layer 130 side of the CF substrate 120.

When a voltage is applied between the pixel electrodes 111 and the common electrode 124, an electric field is generated in the vertical direction, and this electric field drives the liquid crystal of the liquid crystal layer 130. This makes possible the display of images by the differing transmittance of light.

FIG. 17 is a schematic plan view of the array substrate 110 with respect to a single pixel area. In the array substrate 110 shown in FIG. 17, the TFTs 140, which are switching elements, the gate wiring lines 112, the data wiring lines 114, and the pixel electrodes 111 are formed on a transparent substrate 150. More specifically, the pixel electrodes 111, which correspond to pixel areas, are arrayed in a matrix on the array substrate 110, and the TFT 140 is formed in each of those pixel areas. A large number of the gate wiring lines 112 and a large number of the data wiring lines 114 are formed in order to apply signals to each TFT 140.

Here, it is not possible in the manufacturing process to form the gate wiring lines 112 and the data wiring lines 114, which transmit mutually different signals to the TFTs 140, in the same layer. Therefore, the gate wiring lines 112 and the data wiring lines 114 are respectively formed in different layers via an insulating film. In the example shown in FIG. 17, an intersection 155 is present where the data wiring line 114 in the upper layer extends so as to overlap the gate wiring line 112 in the lower layer. Such an intersection 155 sometimes gives rise to defects in which the data wiring line 114 in the upper layer disconnects due to the difference in level of the gate wiring line 112 in the lower layer.

### RELATED ART DOCUMENTS

### Patent Documents

Patent Document 1: Japanese Patent Application Laid-Open Publication No. 2007-310351
Patent Document 2: Japanese Patent Application Laid-Open Publication No. 2001-343669

### SUMMARY OF THE INVENTION

### Problems to be Solved by the Invention

As a countermeasure to this disconnection problem, in Patent Document 1 an attempt is made to prevent the disconnection of the data wiring line 114 by forming a buffer pattern in the vicinity of the gate wiring line 112 in the bottom layer. In other words, in Patent Document 1 an attempt is made to prevent disconnection of source wiring lines as a result of the difference in level at the overlapping section by forming a buffer pattern in the vicinity of the gate wiring line, thereby smoothing the slope on the portion of the source wiring lines that overlaps the pattern of the gate wiring lines.

However, there could be times when a buffer pattern cannot be formed in the vicinity of the gate wiring line 112 in the lower layer, and even if the slope of the overlapping portion is made smooth, there could also be times when disconnection occurs due to corrosion by the etchant.

Patent Document 2 has overlapping parts formed in three directions in order to prevent disconnection due to corrosion by the etchant at portions where the source wiring lines overlap the gate wiring lines. However, with the method used in Patent Document 2, because the width of the source wiring lines is expanded, parasitic capacitance is formed between the metal (the gate metal) that forms the gate wiring lines and the metal (the source metal) that forms the source wiring lines. Therefore, the parasitic capacitance adversely affects the driving of the liquid crystal panel.

The present invention was made in view of the above, and primarily aims at providing an array substrate for a liquid crystal panel that can suppress disconnection of source wiring lines, and a liquid crystal panel.

### Means for Solving the Problems

An array substrate for a liquid crystal panel according to the present invention is an array substrate for a liquid crystal panel with pixels arranged in a matrix having rows and columns, including: auxiliary capacitance wiring that extends in a row direction; and source wiring that is located in an upper layer above the auxiliary capacitance wiring and that extends in a column direction, wherein the source wiring located in the upper layer has an intersection wiring portion on an intersection region of the auxiliary capacitance wiring and the source wiring, and wherein the intersection wiring portion includes: a first portion that continues to a main body part of the source wiring and that extends in the row direction; and a second portion that continues to the first portion and that extends in a direction different than the row direction.

In a preferred embodiment, the second portion of the source wiring extends in the column direction, and the intersection wiring portion includes: the first portion; the second portion that extends perpendicularly from the first portion; and an additional first portion that extends perpendicularly from the second portion and that leads to the main body part.

In a preferred embodiment, the first portion and the additional first portion extend in the row direction so as to cover each outer edge of the auxiliary capacitance wiring located in a lower layer.

In a preferred embodiment, a width of the auxiliary capacitance wiring becomes narrower on the intersection region.

In a preferred embodiment, a width of the source wiring on the main body part is the same size as a width of the second portion on the intersection wiring portion.

In a preferred embodiment, the intersection wiring portion including the first portion and the second portion is formed on all intersection regions of the auxiliary capacitance wiring and the source wiring.

In a preferred embodiment, the intersection wiring portion includes: the first portion that forks from the main body part of the source wiring; the second portion that is connected to the forked first portion, and an additional first portion that connects the second portion and the main body part.

In a preferred embodiment, the forked first portion and the additional first portion respectively extend in the row direction.

In a preferred embodiment, the second portion includes a portion that extends at an angle with respect to the column direction.

In a preferred embodiment, the array substrate further includes gate wiring that extends in the row direction, wherein the source wiring is located in an upper layer above the gate wiring, and wherein the source wiring located in the upper layer overlaps the gate wiring in a straight-line area at an intersection region of the gate wiring and the source wiring.

In a preferred embodiment, the array substrate further includes thin film transistors respectively formed on the pixels arranged in a matrix, wherein the thin film transistors each include: a source electrode that extends from the source wiring; and a drain electrode arranged opposing the source electrode, wherein drain wiring that is to be connected to a pixel electrode extends from the drain electrode, and wherein an end of the drain wiring is connected to the auxiliary capacitance wiring.

The source wiring is made of copper.

A liquid crystal panel according to the present invention includes the array substrate for a liquid crystal panel; a color filter substrate arranged opposing the array substrate; and a liquid crystal layer arranged between the array substrate and the color filter substrate.

A liquid crystal display device according to the present invention includes the liquid crystal panel, and a backlight unit that radiates light to the liquid crystal panel.

### EFFECTS OF THE INVENTION

According to the present invention, source wiring lines have an intersection wiring portion on an intersection region of the auxiliary capacitance wiring lines, which extend in the row direction, and the source wiring lines, which extend in the column direction. The intersection wiring portion is provided with a first portion that extends in the row direction, and a second portion that extends in a direction different than the row direction. Therefore, the source wiring lines overlap the auxiliary capacitance wiring lines on the first portion, which extends in the row direction on the intersection region, and thus an array substrate for a liquid crystal panel that can suppress disconnection of source wiring lines can be realized.

### BRIEF DESCRIPTION OF THE DRAWINGS

FIG. 1 is an exploded perspective view for explaining a liquid crystal display device 100 according to one embodiment of the present invention.

FIG. 2 is an enlarged top view of an array substrate 11 for a liquid crystal panel according to one embodiment of the present invention.

FIG. 3 is a partially enlarged view schematically showing a top configuration of an array substrate 210 of a comparison example.

FIG. 4(a) is an enlarged view of an intersection region 245 in a comparison example, and FIG. 4(b) is a cross-sectional view of the intersection region 245.

FIGS. 5(a) and (b) are a plan view and a cross-sectional view, respectively, for explaining a disconnection 246 that occurs at a portion 242 that a source wiring line 234 overlaps.

FIGS. 6(a) and 6(b) are plan views for explaining the disconnection 246 that occurs at the portion 242 that the source wiring line 234 overlaps.

FIGS. 7(a) and 7(b) are plan views for explaining when a source wiring line 34 according to one embodiment of the present invention has a corroded area 46 at a different-level area 44.

FIGS. 8(a) to 8(c) are cross-sectional views of steps for explaining a manufacturing process for the source wiring lines 34 according to one embodiment of the present invention.

FIGS. 9(a) to 9(c) are cross-sectional views of steps for explaining a manufacturing process for the source wiring lines 34 according to one embodiment of the present invention.

FIG. 10 is an enlarged top view of a pixel on the array substrate 11.

FIG. 11 is an enlarged top view of a pixel on a modified example of the array substrate 11.

FIGS. 12(a) and 12(b) are top views showing modified examples of an intersection wiring portion 40 on the array substrate 11.

FIG. 13 is a top view showing a modified example of the intersection wiring portion 40 on the array substrate 11.

FIG. 14 is a top view showing a modified example of the intersection wiring portion 40 on the array substrate 11.

FIGS. 15(a) and 15(b) are top views showing modified examples of the intersection wiring portion 40 on the array substrate 11.

FIG. 16 is a perspective view showing a configuration of a conventional liquid crystal panel 1000.

FIG. 17 is a schematic plan view of an array substrate 110 with respect to a single pixel area.

### DETAILED DESCRIPTION OF EMBODIMENTS

Embodiments of the present invention will be explained below with reference to the drawings. In the drawings below, for simplicity of description, constituting elements having substantially identical functions will be denoted by identical reference characters. The present invention is not limited to the following embodiments.

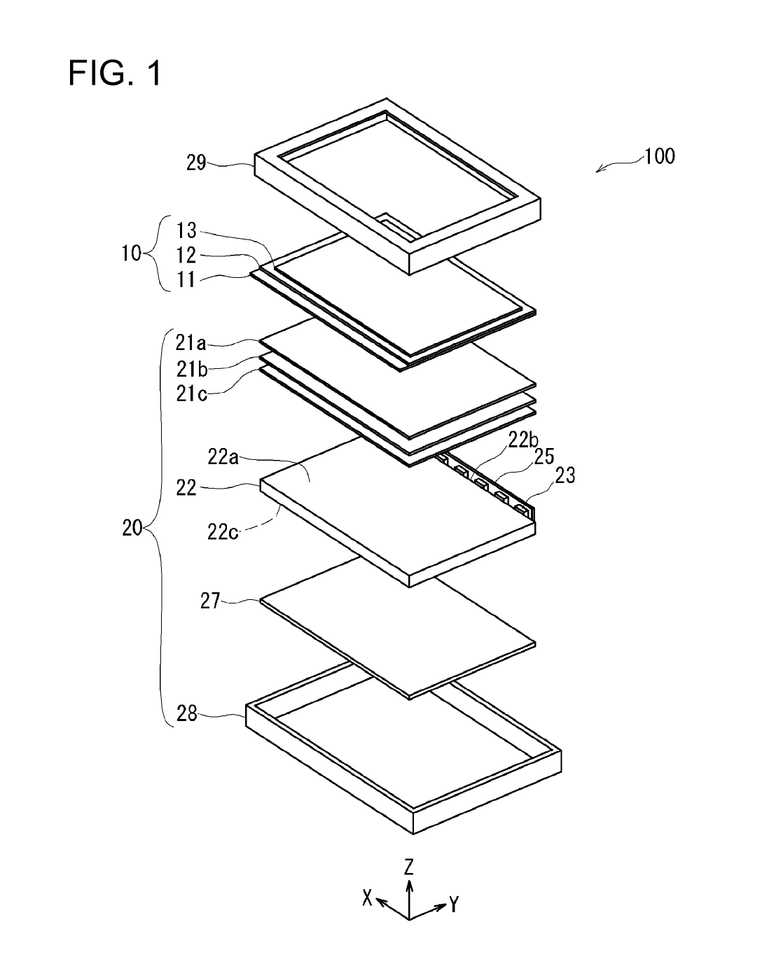

FIG. 1 is an exploded perspective view schematically showing the configuration of a liquid crystal display device 100 according to one embodiment of the present invention. As shown in FIG. 1, the liquid crystal display device 100 of the present embodiment is capable of displaying images. The liquid crystal display device 100 is made of a liquid crystal panel 10, and a backlight unit 20 that radiates light to the liquid crystal panel 10. The liquid crystal panel 10 of the present embodiment has a size of 20 inches to 110 inches (typically 32 inches to 60 inches), for example.

In general, the liquid crystal panel 10 of the present embodiment has a rectangular shape as a whole, and is made of a pair of transparent substrates (glass substrates) 11 and 12. Both substrates 11 and 12 are arranged opposing each other, and a liquid crystal layer (not shown) is provided therebetween. The liquid crystal layer is made of a liquid crystal material, the optical specifics thereof changing by an electric field applied between the substrates 11 and 12.

A sealant (not shown) is provided on the outer margins of the substrates 11 and 12 to seal the liquid crystal layer. Polarizing plates 13 and 13 are respectively attached to the outer surfaces of both substrates 11 and 12. In the present embodiment, the rear side substrate 11 is an array substrate (a TFT substrate) 11, whereas the front side substrate 12 is a color filter substrate (a CF substrate) 12.

The array substrate 11 of the present embodiment is an array substrate for a liquid crystal panel where pixels are arranged in a matrix having rows and columns. As will be described in detail later, the configuration of the present embodiment has gate wiring lines extending in the row direction, and source wiring lines extending in the column direction. A thin film transistor (TFT) is arranged on each pixel. The row direction and column direction are for convenience, and the row direction may mean the horizontal direction, and the column direction may mean the vertical direction, or the relationship thereof may be reversed.

The backlight unit 20 of the present embodiment is a light source unit for radiating light to the liquid crystal panel 10. The backlight unit 20 of the example shown in FIG. 1 is an edge-lit backlight unit. The backlight unit 20 of the present embodiment is made of a plurality of light-emitting elements 23, and a light guide plate 22 that radiates light emitted by the light-emitting elements 23 to the liquid crystal panel 10.

The light-emitting elements 23 of the present embodiment are LED elements (point light sources), and in the configuration example shown in FIG. 1 a plurality of the LED elements 23 are placed on a wiring substrate 25. The LED elements 23 are arranged opposing one side surface (an incident surface) 22b of the light guide plate 22, and the light that exits the LED elements 23 enters inside the light guide plate 22 from the incident surface 22b of the light guide plate 22.

The light guide plate 22 is an optical member that radiates the light, which has entered the incident surface 22b, from a light-emitting surface (a principal surface) 22a as planar light. The light guide plate 22 is made of an acrylic plate, for example. A dot pattern (not shown) that acts as a reflective layer is formed on a bottom surface 22c of the light guide plate 22 of the present embodiment. This dot pattern is formed by printing using ink or the like that forms a reflective pattern or a diffusion pattern.

Optical sheets 21 (21a to 21c) are arranged between the light guide plate 22 and the liquid crystal panel 10. In this example, the optical sheets 21a to 21c are, respectively, a lens sheet, a prism sheet, and a diffusion plate, for example. The configuration of the optical sheets 21 is not limited thereto, and other configurations may be adopted.

Furthermore, the backlight unit 20 of the present embodiment is provided with a backlight chassis 28 that stores the light guide plate 22. The backlight chassis 28 of the present embodiment is made of a metal material (aluminum, iron, or the like, for example), and is a sheet metal member that covers the entire rear surface of the liquid crystal display device 100. A reflective sheet 27 is arranged between the backlight chassis 28 and the light guide plate 22.

A bezel 29 is provided on the liquid crystal display device 100 of the present embodiment. The bezel 29 is made of a metal material (aluminum or iron, for example), and is a frame member fixing the liquid crystal panel by holding the outer margins thereof. In the configuration of the present embodiment, the bezel 29 is installed on the backlight chassis 28 in a state where the liquid crystal panel 10, the optical sheets 21, the light guide plate 22, the wiring substrate (the LED substrate) 25 whereupon the LED devices 23 are mounted, and the reflective sheet 27 are stored in the backlight chassis 28.

In the configuration shown in FIG. 1, the edge-lit backlight unit 20, which uses the LED elements 23, is shown, but the configuration is not limited to this. In the present invention, the edge-lit backlight unit 20 can also use other light-emitting elements (cold-cathode fluorescent lamps (CCFLs), for example), for example. Alternatively, the backlight unit 20 can also be a direct-lit type. LED elements, cold-cathode fluorescent lamps, or the like can be used as light-emitting elements when the direct-lit backlight unit 20 is used.

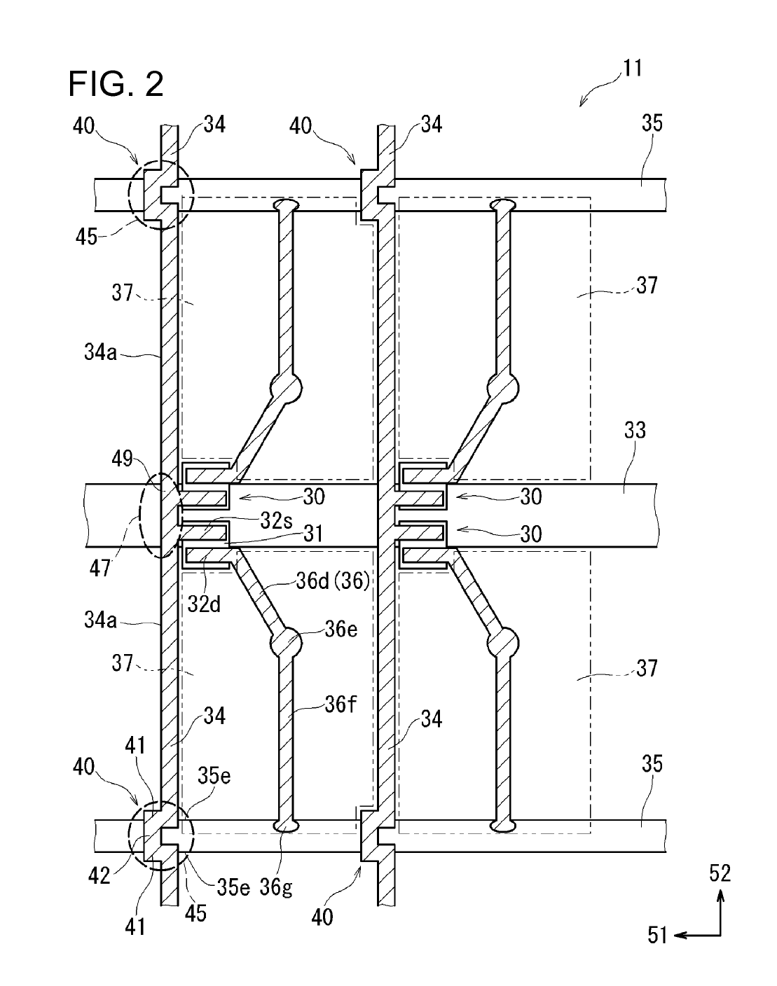

Next, configurations of the present embodiment will be explained with reference to FIG. 2. FIG. 2 is a partially enlarged view schematically showing a top configuration of an array substrate 11 of the present embodiment.

The array substrate 11 of the present embodiment has pixels arranged in a matrix having rows and columns. In this example, a gate wiring line 33 extends in a row direction (arrow 51), and source wiring lines 34 extend in a column direction (the direction of arrow 52). TFT elements 30 are formed as switching elements on intersections of the gate wiring line 33 and the source wiring lines 34.

The TFT elements 30 are made of a semiconductor layer 31 that acts as a channel layer, a source electrode 32s that extends from a source wiring line 34, and a drain electrode 32d that is arranged opposing the source electrode 32s. The semiconductor layer 31 is made of silicon (such as amorphous silicon or polycrystalline silicon), for example. The area of the gate wiring line 33 located below the semiconductor layer 31 acts as a gate electrode. A gate insulating film is formed between the gate electrode and the semiconductor layer 31. The source electrode 32s and the drain electrode 32d are arranged on the surface of the semiconductor layer 31, and the space between the source electrode 32s and the drain electrode 32d acts as a channel region.

Drain wiring lines 36 extend from the drain electrodes 32d. In the example shown in FIG. 2, a part 36d of each drain wiring line 36 is connected to a pixel electrode 37 at a connection area 36e. The pixel electrode 37 is an electrode that defines each pixel, and is formed of a transparent electrode (ITO, for example). When the color filter substrate 12 has a configuration of three primary colors (R, G, B), the pixels of the present embodiment are areas that correspond to the R (red), G (green), and B (blue). When the three regions of R, G, B are collectively referred to a pixel, the area where the pixel electrode 37 is located may be referred to as a sub-pixel area or a picture-element area. When the color filter substrate 12 has a configuration of four primary colors (R, G, B, Y), the pixels of the present embodiment are areas that correspond to the R (red), G (green), B (blue), and Y (yellow). In addition, the pattern of the pixel electrode 37 is shown in the configuration of the present embodiment as an example, and suitable specific patterns may be adopted as appropriate.

In the configuration of the present embodiment, an auxiliary capacitance (Cs) is formed on the array substrate 11. Auxiliary capacitance wiring lines (Cs wiring lines) 35 are formed on the array substrate 11. Here, the auxiliary capacitance (Cs) is formed by a Cs electrode located on part of the Cs wiring lines 35, an insulating film (not shown), and the pixel electrode 37. The insulating film (the dielectric layer) that forms the auxiliary capacitance (Cs) is located between the Cs electrode and the pixel electrode 37, and the auxiliary capacitance (Cs) is formed at each intersection between the Cs wiring lines 35 and the pixel electrodes 37. The auxiliary capacitance (Cs) supplies an electric charge to the liquid crystal layer when the gate signal is in an OFF period, and serves to maintain the brightness of the pixel. In the configuration of the present embodiment, an end 36g of each drain wiring line 36 is connected to the auxiliary capacitance wiring lines (the Cs wiring lines) 35. Specifically, the drain wiring lines 36 are connected to the Cs wiring lines 35 via draw-out parts 36d and 36f.

In the configuration of the present embodiment, the Cs wiring lines 35 extend in the row direction (arrow 51), in a manner similar to the gate wiring line 33. The source wiring lines 34 are located in an upper layer above the Cs wiring lines 35, and intersection regions 45 are present on the array substrate 11 where the source wiring lines 34 and the Cs wiring lines 35 intersect each other. The source wiring lines 34 have intersection wiring portions 40 at the intersection regions 45.

The intersection wiring portion 40 of the source wiring line 34 includes a first portion 41 that continues to a main body part 34a of the source wiring lines 34, and a second portion 42 that continues to the first portion 41. The first portion 41 extends in a different direction than the direction (the column direction 52) in which the main body part 34a extends. In the example shown in FIG. 2, the first portion 41 extends in the direction (the row direction 51) in which the Cs wiring lines 35 extend. The second portion 42 extends in a direction different than the row direction 51. Specifically, the second portion 42 extends in the same direction as the main body part 34a, and extends in the column direction 52 in the example shown in FIG. 2. Therefore, the first portion 41 and the second portion 42 are connected to each other at a right angle corner. The main body part 34a of the source wiring line 34 is a portion that extends linearly and that is located outside the intersection wiring portion 40.

In addition, in this example, an additional first portion 41 extends from the second portion 42 and connects to the main body part 34a of the source wiring line 34. This additional first portion 41 extends in the row direction 51. Therefore, in this example, the additional first portion 41 perpendicularly extends from the second portion 42 and connects to the main body portion 34a. The first portion 41, which is on the intersection wiring portion 40 of the source wiring line 34, extends so as to cover an outer edge 35e of the Cs wiring line 35 located in the lower layer. The additional first portion 41 also extends so as to cover an outer edge 35e of the Cs wiring line 35.

Furthermore, in the configuration of the present embodiment, the gate wiring line 33 is formed on the same level layer as the Cs wiring lines 35. Therefore, the source wiring lines 34 are located in an upper layer above the gate wiring line 33. An intersection region 47 is present on the array substrate 11 of the present embodiment where the source wiring lines 34 and the gate wiring line 33 intersect each other. In the example shown, the source wiring lines 34 have a straight-line area 49 that extends in the column direction 52 on the intersection region 47. In other words, the source wiring line 34 extends in the column direction 52 on the intersection region 47 with the gate wiring line 33, in a manner similar to the main body part 34a.

In the configuration of the present embodiment, the source wiring lines 34 are made of copper. The Cs wiring lines 35 and the gate wiring lines 33 are also made of copper. The source wiring lines 34, the Cs wiring lines 35, and the gate wiring lines 33 are not limited to copper wiring lines, and may be made of another metal material (aluminum), or made of a multilayer film (Cu and Mo, or Cu and Ti, for example). Additionally, the source wiring lines 34 (the copper wiring lines, for example) may be made of a material different than the Cs wiring lines 35 and the gate wiring lines 33.

According to the configuration of the present embodiment, the source wiring lines 34 have the intersection wiring portion 40 at the intersection regions 45 of the Cs wiring lines 35, which extend in the row direction 51, and the source wiring lines 34, which extend in the column direction 52. The intersection wiring portion 40 of the source wiring lines 34 is provided with the first portion 41, which extends in a different direction than the column direction 52, and the second portion 42, which includes a portion that extends in the column direction 52. Therefore, the source wiring lines 34 can overlap the Cs wiring lines 35 at the first portion 41 (in the example shown in FIG. 2, the first portion 41 that extends in the row direction 51), which extends in a direction different than the column direction 52 at the intersection region 45. As a result, an array substrate 11 for a liquid crystal panel that can suppress disconnection of the source wiring lines 34 can be realized.

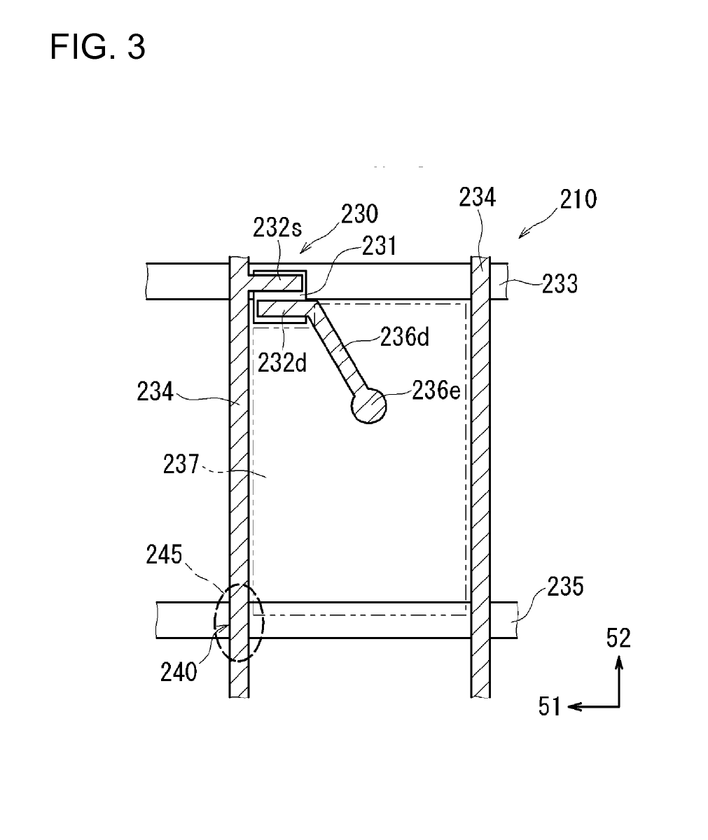

The causes for disconnection of the source wiring lines will be explained with reference to FIGS. 3 to 5. FIG. 3 is an enlarged view schematically showing a top configuration of a part of an array substrate 210 of a comparison example.

In the array substrate 210 of the comparison example shown in FIG. 3, a gate wiring line 233 and a Cs wiring line 235 that extend in the row direction 51, and source wiring lines 234 that extend in the column direction 52 are formed. A TFT element 230 is formed of a semiconductor layer 231, a source electrode 232s, and a drain electrode 232d. A drain wiring line 236d that extends from the drain electrode 232d is connected to a pixel electrode 237 at a connection area 236e. Although not shown, the end of the drain wiring line 236d is connected to the Cs wiring line 235.

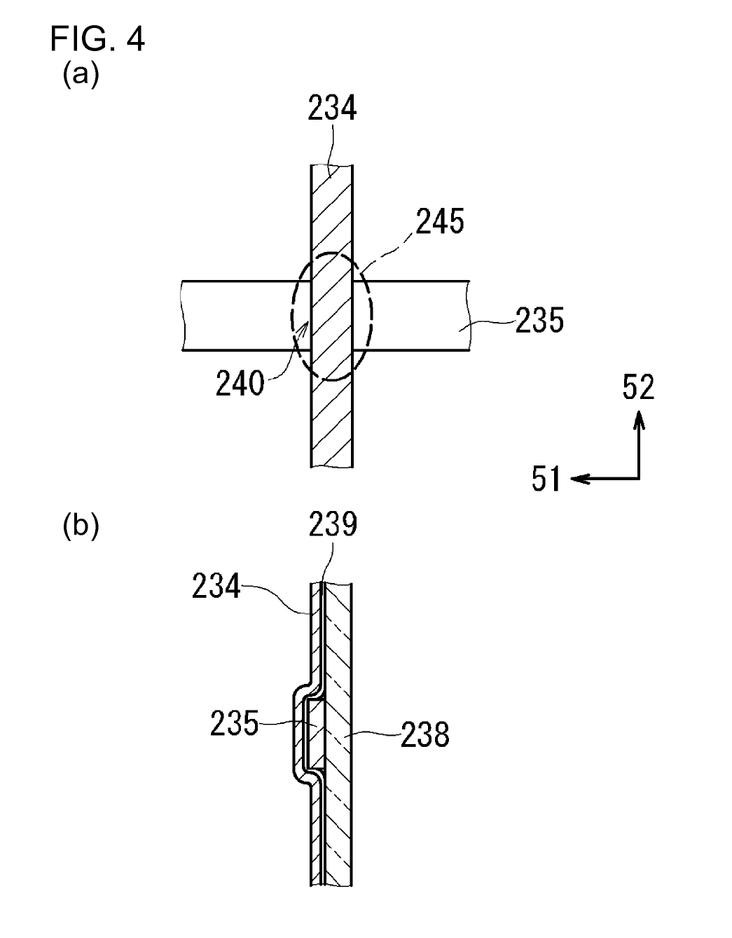

In this comparison example, the source wiring lines 234 do not bend, but rather extend in the column direction 52 as a straight-line area 240 at the intersection region 245 of the source wiring lines 234 and the Cs wiring line 235. FIG. 4(a) is an enlarged view of an intersection region 245, and FIG. 4(b) is a cross-sectional view of the intersection region 245.

As shown in FIG. 4(b), the Cs wiring line 235 extends on a glass substrate 238. An insulating film 239 is formed on the glass substrate 238 so as to cover the Cs wiring line 235. The source wiring line 234 is formed on the insulating film 239. As shown, the source wiring line 234 extends so as to overlap a level difference formed by the Cs wiring line 235 at the intersection region 245.

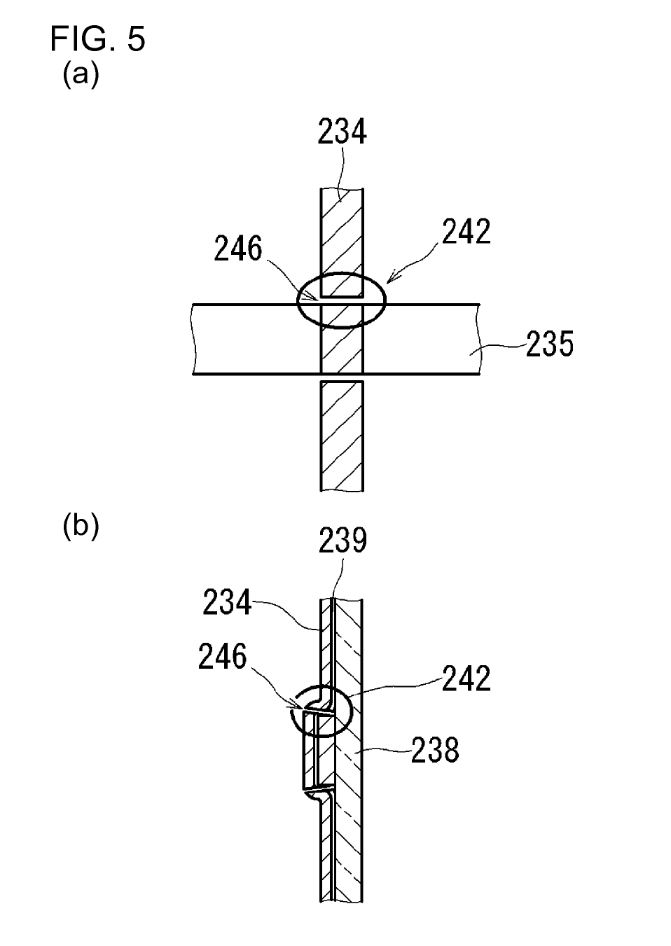

The source wiring line 234 is formed by patterning a metal film through etching. Therefore, as shown in FIGS. 5(a) and 5(b), the possibility increases of disconnection (246) occurring at an area (242) where the source wiring line 234 overlaps the level difference part of the Cs wiring line 235 due to the effect of corrosion because of residues or the like from etching. Furthermore, when the source wiring line 234 is a copper wiring line, disconnection (246) sometimes occurs at the different-level part (242) due to oxidation corrosion of the copper wiring line.

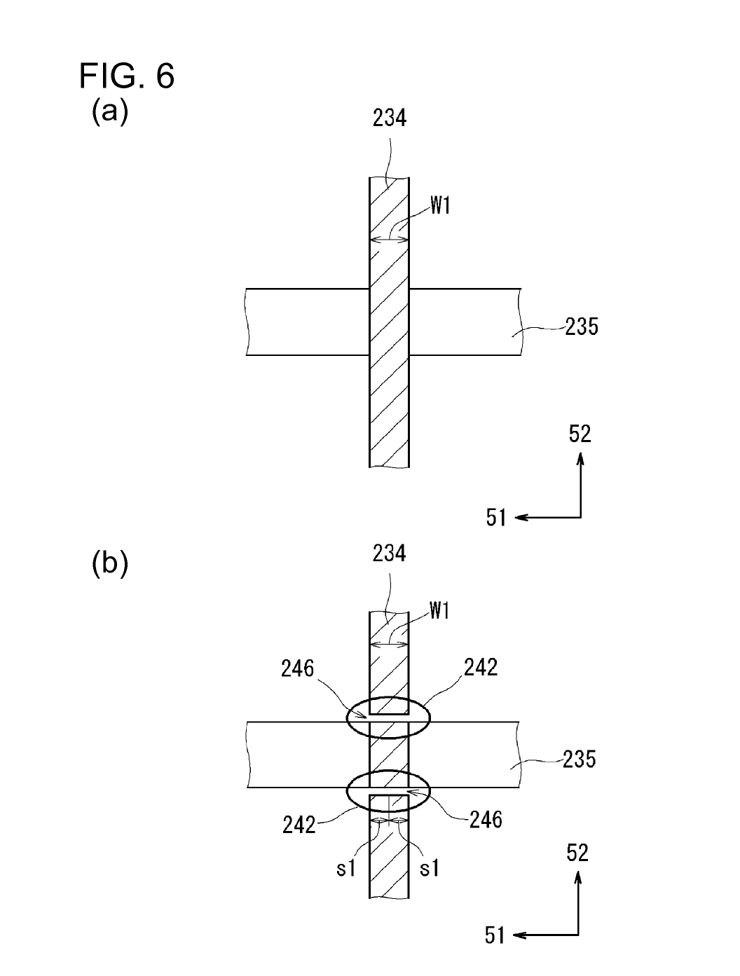

If the width of the source wiring line 234 in the comparison example is W1 as shown in FIG. 6(a), then if a corrosion of width s1 (s1=W1/2) occurs from both sides as shown in FIG. 6(b), disconnection 246 of the source wiring line 234 will occur at the different-level parts (242).

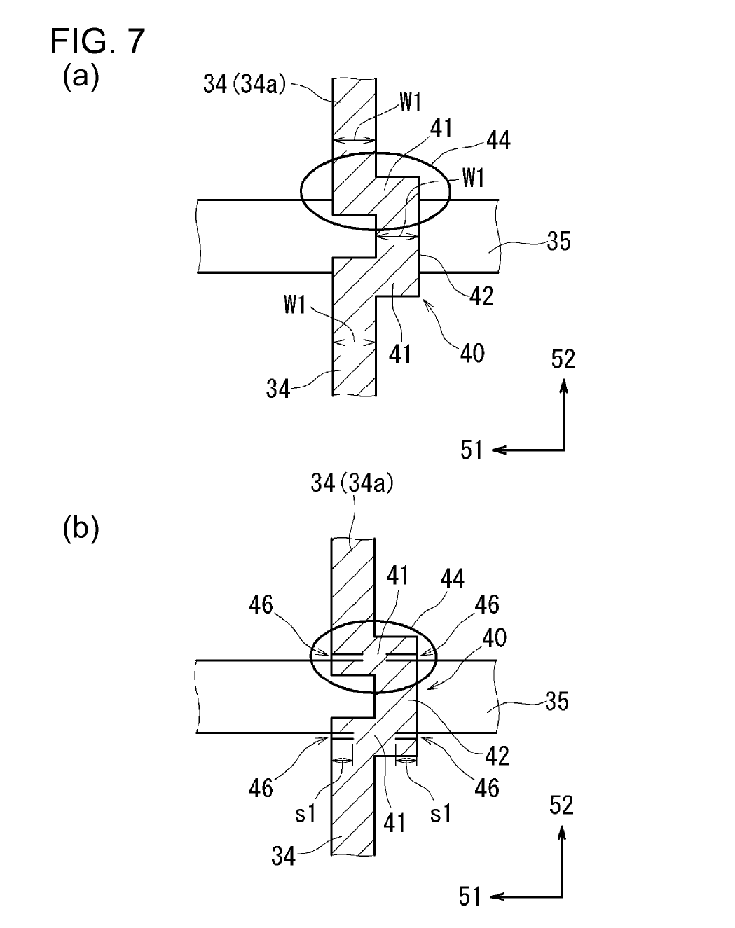

Here, as shown in FIG. 7(a), the width of the source wiring line 34 (the main body part 34a) of the present embodiment is W1, and the width of the second portion 42 is also W1. As shown in FIG. 7(b), disconnection of the source wiring line 34 can be suppressed even if a corroded area 46 of width s1 occurs from both sides at a different-level area (an overlap area) 44. In other words, even if the width of the source wiring line 34 is W1, the width of the source wiring line 34 at the different-level area 44 can be substantially widened in the direction (51) in which the Cs wiring line 35 extends due to the first portion 41, and as a result disconnection of the source wiring line 34 at the different-level area 44 can be suppressed.

According to the configuration of the present embodiment, the structure is such that the first portion 41 is extended in the row direction 51 (the Cs wiring line scanning direction) while the main body part 34a and the second portion 42 of the source wiring line 34 is a constant width of W 1. Due to this structure, disconnection of the source wiring line 34 can be suppressed even if the width of the source wiring line 34 is not widened twice as much or more than W1, for example, at the intersection region (the different-level part 44). Namely, if the width of the source wiring 34 is widened twice as much or more than W1, for example, at the intersection region (the different-level part 44), then disconnection can be suppressed; however, this causes parasitic capacitance to occur. In other words, if the width of the source wiring line 34 is increased at the intersection region (the different-level part 44), then the parasitic capacitance between the source wiring line 34 and the Cs wiring line 35 at the intersection region (the different-level part 44) will increase, and this will cause signal delays and the like as a result. In the configuration of the present embodiment, disconnection of the source wiring 34 at the intersection region (the different-level part 44) can be suppressed, while restraining an increase in such parasitic capacitance.

According to the configuration of the present embodiment, as shown in FIG. 2 the source wiring line 34 extends in a straight direction at the intersection region 47 of the source wiring line 34 and the gate wiring line 33. In other words, the source wiring line 34 has a straight-line area 49 that extends in the column direction 52 at the intersection region 47 with the gate wiring line 33. Therefore, according to the configuration of the present embodiment, an increase in parasitic capacitance between the source wiring line 34 and the gate wiring line 33 can be suppressed, as compared to when the width of the source wiring line 34 is widened at the intersection region 47 with the gate wiring line 33.

In the configuration of the present embodiment, the width of the gate wiring line 33 is approximately twice (twice or more, for example) the width of the Cs wiring line 35. Therefore, if the width of the source wiring line 34 is widened at the intersection region 47 with the gate wiring line 33, the effect of increased parasitic capacitance is significant, and therefore the problem of signal delays due to the increase of parasitic capacitance becomes significant. In the configuration of the present embodiment, according to the configuration of the present embodiment the width of the source wiring line 34 at the intersection region 47 with the gate wiring line 33 is the same as the width of the main body part 34a, so the problem of an increase in parasitic capacitance can be suppressed.

In addition, depending on the relationship to the structure of the TFT elements 30, the intersection wiring portion 40 may be formed on the source wiring line 34 at the intersection region 47 with the gate wiring line 33, in a manner similar to the intersection region 45 of the Cs wiring line 35. Specifically, at the intersection region 47 it is possible to provide the intersection wiring portion 40, which includes the first portion 41 that continues to the main body part 34a of the source wiring line 34 and extends in the longitudinal direction of the gate wiring line 33 (the row direction 51), and the second portion 42 that extends in the same direction (the column direction 52) as the main body part 34a. Here, if the width (W1) of the second portion 42 is set the same as the width (W1) of the main body part 34a of the source wiring line 34, then the effect of increased parasitic capacitance can be suppressed.

In the configuration of the present embodiment, conditions such as the width of the wiring lines and the like are demonstrated by way of example as follows. The width (W1) of the source wiring line 34 is 5-8 μm, for example. The width of the gate wiring line 33 is 10 to 20 μm, for example. The width of the Cs wiring line 35 is 10-20 μm, for example. The thickness of the source wiring line 34 is 3000-4500 Å, for example, and the thickness of the gate wiring line 33 and the Cs wiring line 35 is 3000-5000 Å, for example.

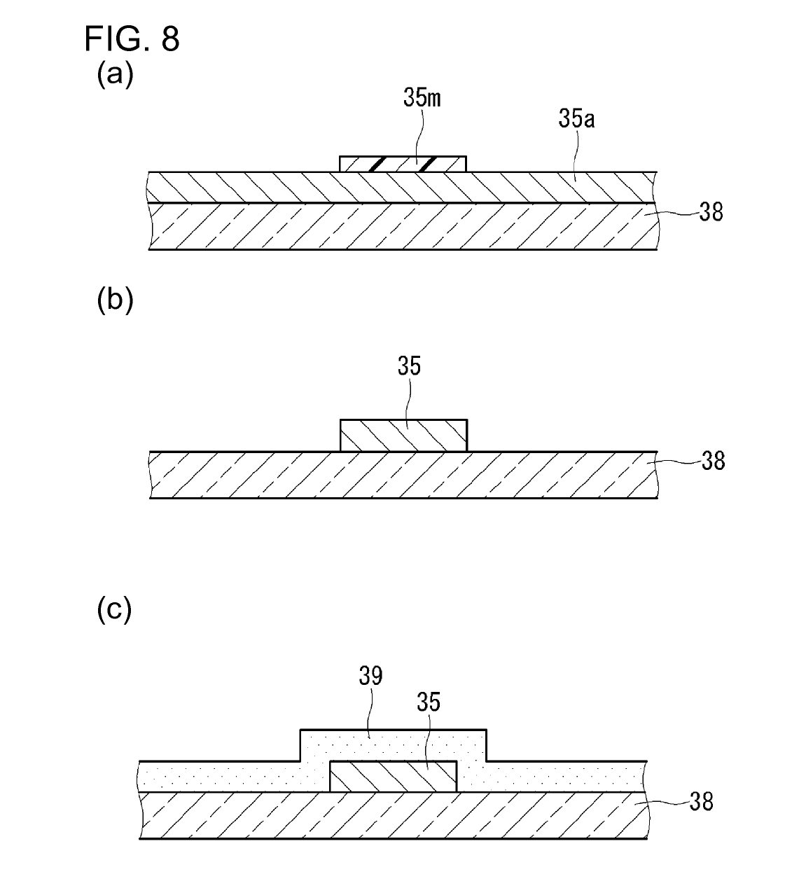

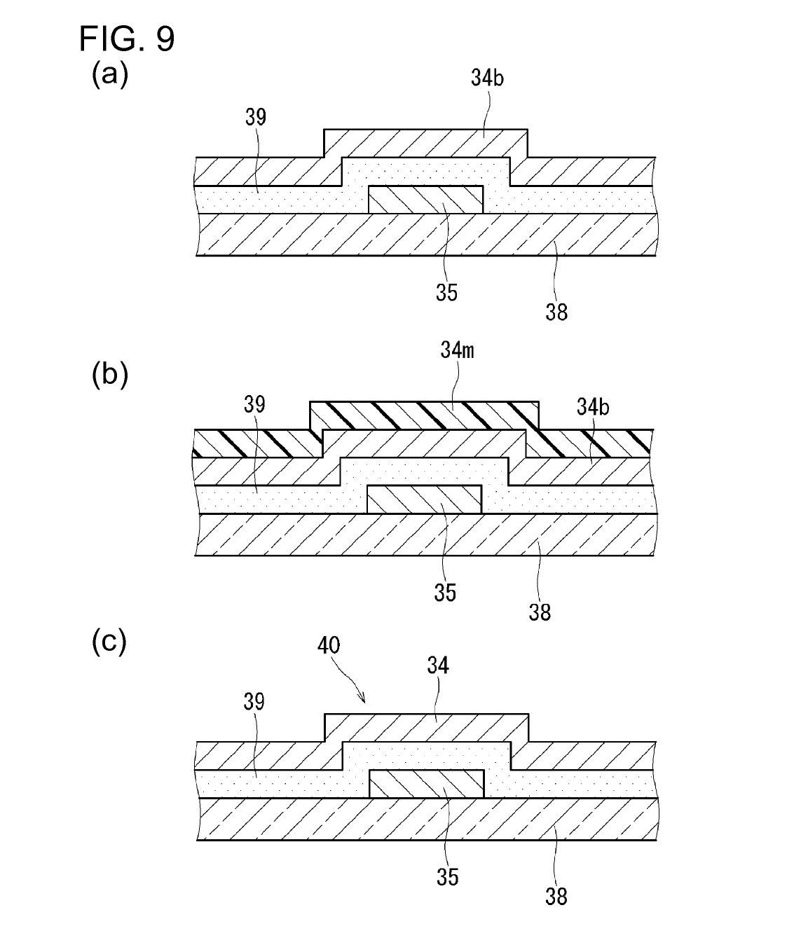

Next, a manufacturing method of the source wiring line 34, which includes the intersection wiring portion 40 in the present embodiment, will be explained with reference to FIGS. 8(a) to 9(c). FIGS. 8(a) to 8(c) and FIGS. 9(a) to 9(c) are cross-sectional views of steps for explaining the manufacturing process for the source wiring line 34.

First, as shown in FIG. 8(a), a metal film 35a that acts as the material for the Cs wiring line 35 is deposited on a glass substrate 38, and then a resist pattern 35m, which defines the pattern of the Cs wiring line 35, is formed on the metal film 35a. This metal film 35a is also the material (the gate metal) of the gate wiring line 33, and the resist pattern 35m also includes a pattern that defines the pattern of the gate wiring line 33. In this example, the metal film 35a is made of copper, and the resist pattern 35m is a pattern made of a resin and formed by photolithography.

Next, as shown in FIG. 8(b), the Cs wiring line 35 is formed by wet-etching the metal film 35a with the resist pattern 35m as the mask. The gate wiring line 33 is also formed by this wet-etching. Here, the etching solution (the etchant) is a liquid solution that includes a fluorinated compound, for example. After wet-etching, the resist pattern 35m is removed.

Next, as shown in FIG. 8(c), an insulating film 39 is formed on the glass substrate 38 so as to cover the Cs wiring line 35. The insulating film 39 is made of a silicon nitride, for example, and has a thickness of 3000-4500 Å, for example.

Next, as shown in FIG. 9(a), a metal film 34b that acts as the material (the source metal) of the source wiring line 34 is laminated on the insulating film 39. In this example, the metal film 34b is made of copper. Next, a resist pattern 34m that defines the pattern of the source wiring line 34 is formed on the metal film 34b. The resist pattern 34m includes a pattern that defines the intersection wiring portion 40, which includes the first portion 41 and the second portion 42. The resist pattern 34m is a pattern made of a resin and formed by photolithography.

Then, as shown in FIG. 9(c), the source wiring line 34 is formed by wet-etching the metal film 34b with the resist pattern 34m as the mask. Here, the etching solution (the etchant) is a liquid solution that includes a fluorinated compound, for example. Finally, the source wiring line 34, which contains the intersection wiring portion 40, is obtained when the resist pattern 34m is removed.

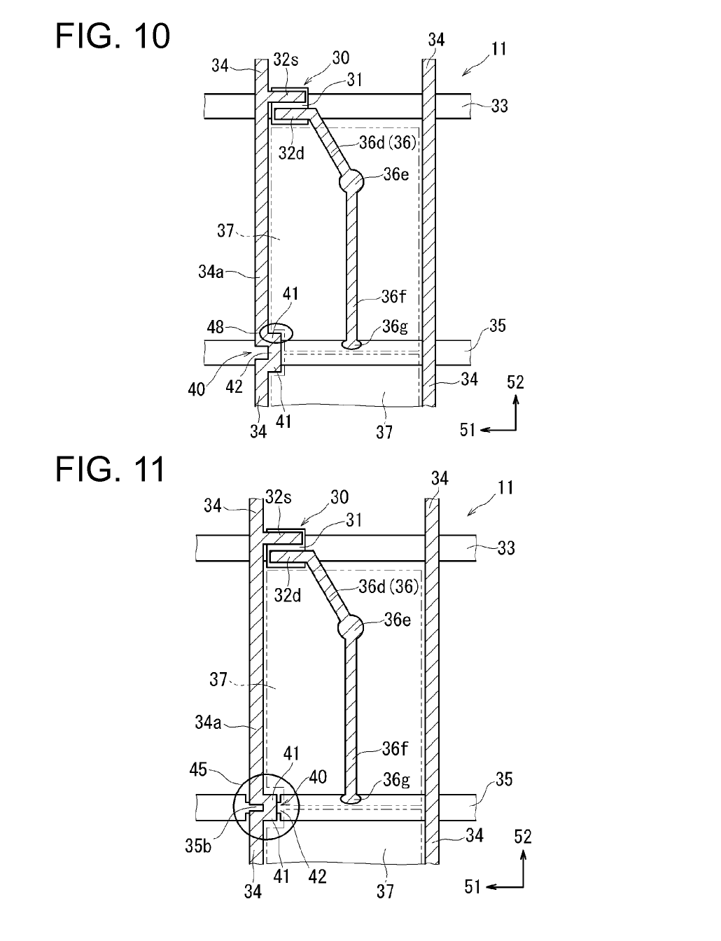

Next, modified examples of the array substrate 11 of the present embodiment will be explained with reference to FIGS. 10 and 11. FIGS. 10 and 11 are enlarged top views of a pixel on the array substrate 11 in the present embodiment.

As shown in FIG. 10, a part (the first portion 41) of the source wiring line 34 is adjacent to a part (a corner part) of the pixel electrode (the transparent electrode) 37 when the intersection wiring portion 40 of the source wiring line 34 is formed on the intersection region 45 with the Cs wiring line 35. In other words, when the source wiring line 34 is bent in a horizontal U-shape to form the intersection wiring portion 40, the first portion 41 of the source wiring line 34 is adjacent to a part of the pixel electrode 37 on a region (the adjacent region) 48 in the drawing, as compared to when the source wiring line 34 is extended in a straight line.

When a part of the source wiring line 34 is adjacent to the pixel electrode 37, the state of the liquid crystal layer in the periphery thereof sometimes changes due to the effects of the electric field when source voltage is applied to the source wiring line 34. Furthermore, it is possible for signal delays to occur due to parasitic capacitance occurring between the source wiring line 34 and the pixel electrode 37. When resolving these problems, as shown in FIG. 11 it is possible to modify the structure of the array substrate 11 of the present embodiment.

In the array substrate 11 shown in FIG. 11, the Cs wiring line 35 has a portion (a narrow-width part 35b) where the width thereof is narrowed on the intersection region 45. The first portion 41 of the source wiring line 34 extends so as to cover an outer edge of the narrow part 35b. The source wiring 34, which has the intersection wiring portion 40 formed as such, can be farther away from the pixel electrode 37 as compared to the configuration example shown in FIG. 10. In other words, in the configuration shown in FIG. 11, the source wiring line 34 can avoid being adjacent to the pixel electrode 37. As a result, changes in the state of the liquid crystal layer due to the effects of the electric field when the source wiring line 34 is adjacent to the pixel electrode 37 can be prevented, and the occurrence of parasitic capacitance between the source wiring line 34 and the pixel electrode 37 can be suppressed.

On the array substrate 11 shown in FIG. 2, the intersection wiring portions 40 are respectively formed at each intersection region 45 of the source wiring lines 34 and the Cs wiring lines 35. However, as shown in FIGS. 10 and 11, it is possible not to form the intersection wiring portions 40 on all of the intersection regions of the source wiring lines 34 and the Cs wiring lines 35, and at some of the intersection regions, straight-line wiring parts may be formed, instead of the intersection wiring portions 40.

In the embodiment described above, the first portion 41 is extended in one direction side, but without being limited thereto, other modified configurations can also be used.

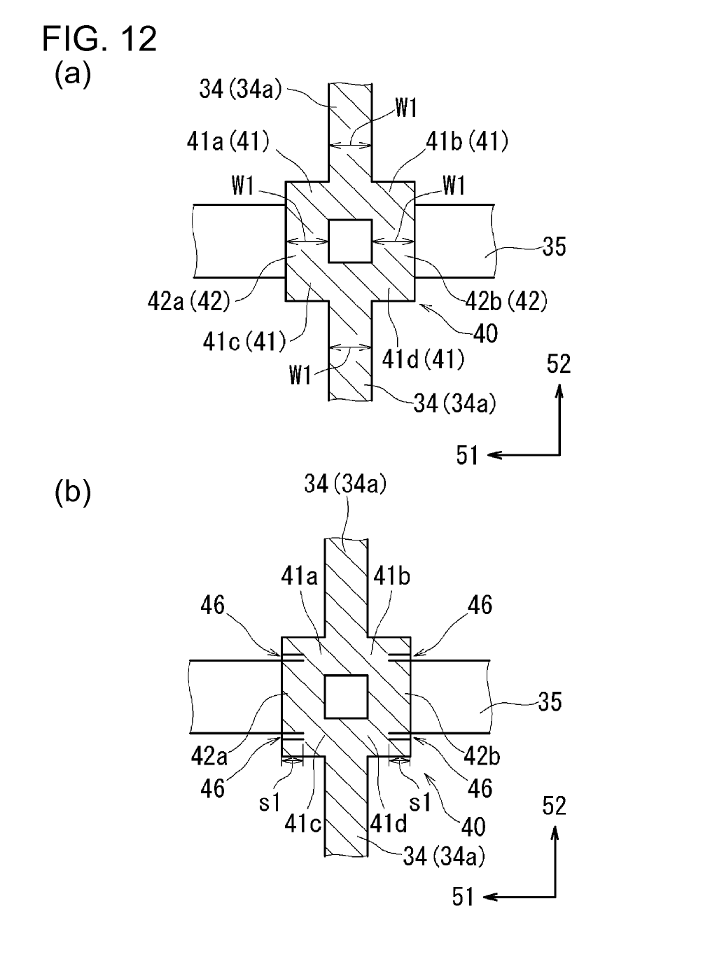

FIG. 12(a) shows a configuration in which the first portion 41 is extended on both sides along the row direction 51. In other words, the first portion 41 (41a and 41b) fork from the main body part 34a of the source wiring line 34 on the intersection wiring portion 40. The second portion 42 (42a and 42b) is connected to the forked first portion 41 (41a and 41b). Furthermore, the additional first portion 41 (41c and 41d) is connected to the second portion 42 (42a and 42b), and the additional first portion 41 (41c and 41d) is connected to the main body part 34a. In this example, the intersection wiring portion 40 has a quadrilateral shape, and the width (W1) of the main body part 34a and the width (W1) of the second portion 42 (42a and 42b) are the same.

As shown in FIG. 12(b), even if the corroded area 46 of the width s1 (s1=W1/2) occurs at the first portion 41 on the intersection region (the different-level part) 45, disconnection of the source wiring line 34 can be suppressed. In other words, even if the corroded area 46 (the four corrosion lines in FIG. 12(b)) occurs along the direction (the row direction 51) in which the Cs wiring line 35 extends, disconnection of the source wiring line 34 can be prevented.

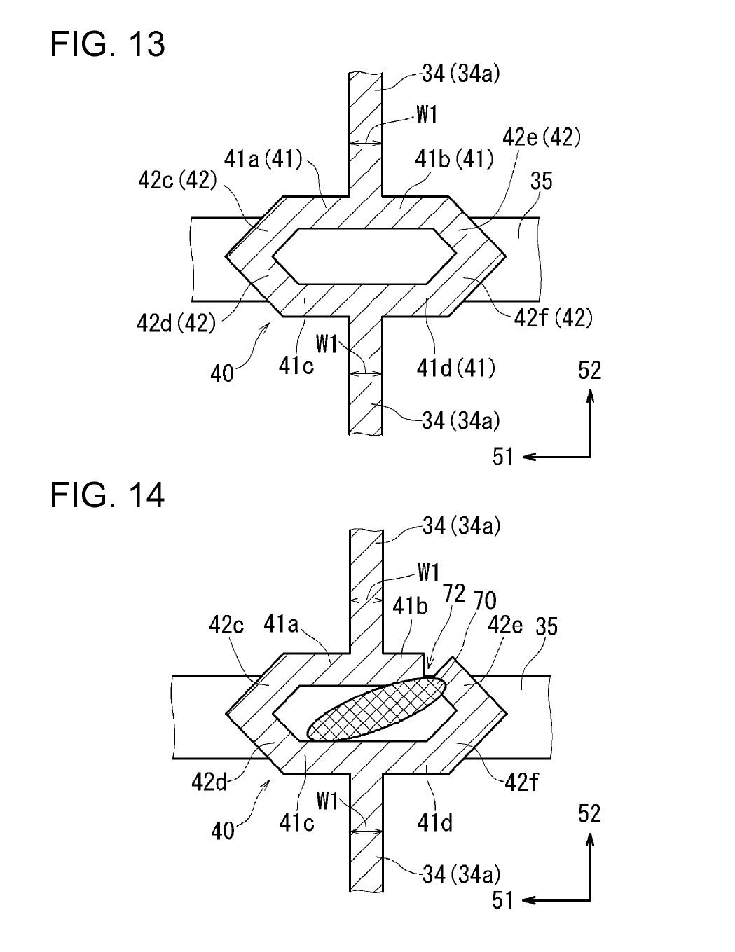

Furthermore, modifications as shown in FIG. 13 are also possible. In the modified example shown in FIG. 13, the second portion 42 includes portions (42c, 42d, 42e, and 42f) that extend not in the column direction 52, but rather at an angle with respect to the column direction 52. Specifically, a first portion 41a and a first portion 41b fork from the main body part 34a of the source wiring line 34. The second portion 42c and the second portion 42d extend from one forked first portion 41a, and are connected to an additional first portion 41c. The second portion 42e and the second portion 42f extend from another forked first portion 41b, and are connected to an additional first portion 41d. In this example, the direction in which the second portion 42 (42c, 42d, 42e, and 42f) extends is at a 45° angle to the column direction 52, but other angles (30°, for example) may also be used.

With the configuration shown in FIG. 13, even if corrosion occurs at the first portion 41 (41a and 41b) of the intersection region (the different-level part) 45, an effect is obtained whereby disconnection of the source wiring line 34 can be suppressed, in a manner similar to the configuration shown in FIGS. 12(a) and 12(b). Furthermore, as shown in FIG. 14, even if a state (arrow 72) of disconnection between a first portion 41b and a second portion 42e occurs due to a foreign object 70 being mixed in during the manufacturing process, the route of the source wiring line 34 can be secured at the first portion 41a, the second portion 42c, the wiring line 34 can be suppressed.

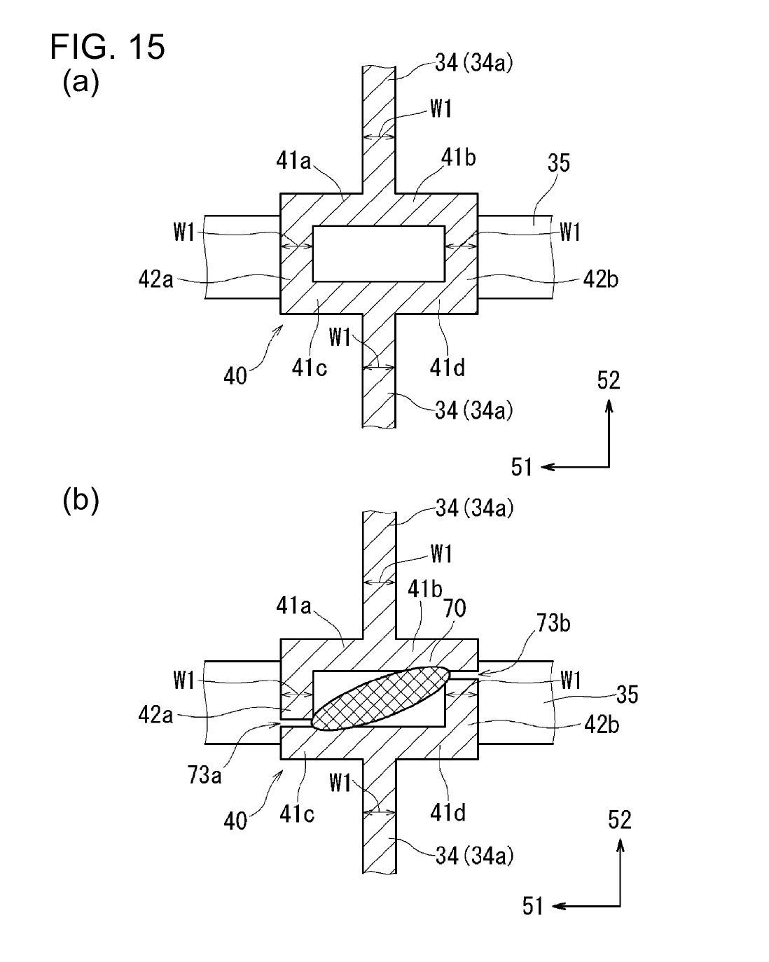

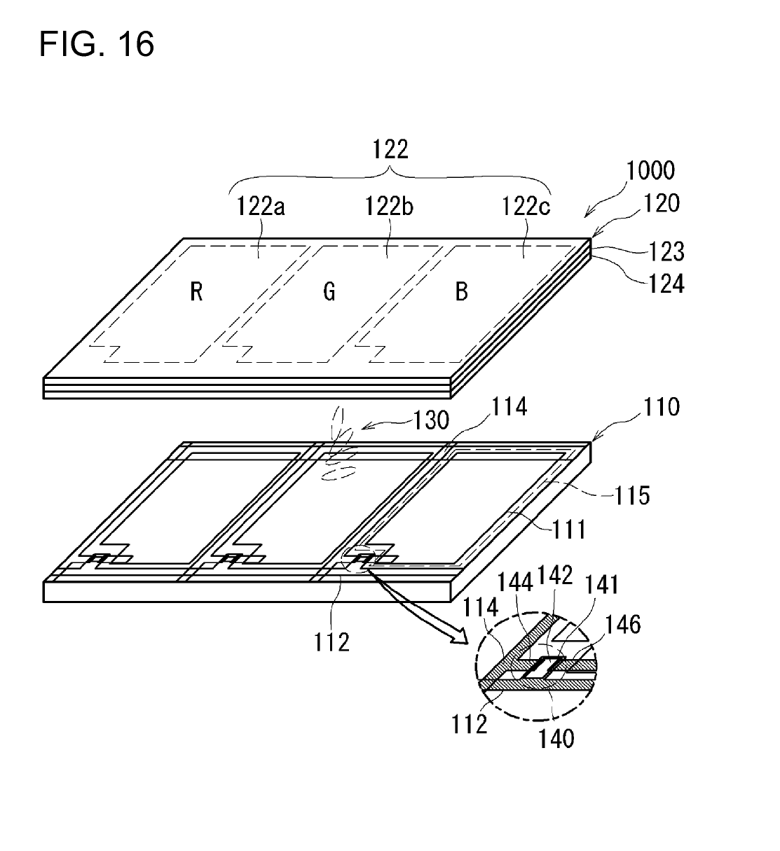

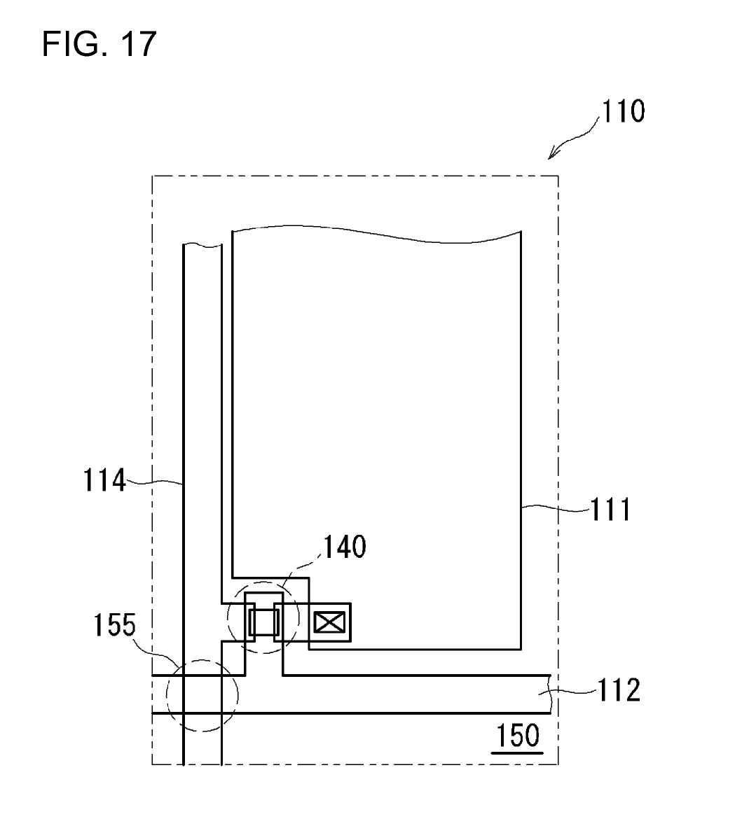

In the configuration shown in FIG. 15(a), the second portion 42a and the second portion 42b extend in the column direction 52. In this configuration, as shown in FIG. 15(b), there is the possibility of disconnection occurring between the first portion 41b and the second portion 42b (see arrow 73b), as well as disconnection occurring between the second portion 42a and the additional first portion 41c (see arrow 73a) if the foreign object 70 similar to that in FIG. 14 is mixed in. In such a case, the connection of the source wiring line 34 will be severed at both routes on the intersection wiring portion 40, and thus disconnection of the source wiring line 34 will occur. In that regard, there is advantage to the structure shown in FIG. 13.

In the example shown in FIG. 13, the second portion 42 (42c, 42d, 42e, and 420, which extends at an angle, is formed in the configuration where the first portion is forked. However, without being limited thereto, it is also possible to form the second portion 42 (42e and 42f, for example), which extends at an angle from the first portion 41, in a configuration such as shown in FIG. 7(a).

In the configuration example described above, the width of the main body part 34a of the source wiring line 34 is made the same as the width of the second portion 42 of the intersection wiring portion 40, but without being limited thereto, a different width may also be used. Typically, the width of the first portion 41, which extends in the row direction, and the width of the second portion 42, which extends in the column direction, can be made the same, but different widths may also be adopted. When the source wiring line 34 is a copper wiring line, it is easy for disconnection to occur due to oxidation corrosion of the copper wiring line. Therefore, in that regard the configuration of the present embodiment demonstrates remarkable effects. When the source wiring line 34 is made of a multilayer film, it is sometimes difficult to choose an etching solution suitable for etching the multilayer film, and sometimes the effect of corrosion becomes stronger due to the type of etching solution used. In such a case, the configuration of the present embodiment also demonstrates remarkable effects.

In the liquid crystal display device 100 of the present embodiment shown in FIG. 1, a control device (not shown) that controls the driving of the liquid crystal panel 10 and/or the light-emitting elements (an LED element, for example) 23 can be included. Such a control device is made of a semiconductor integrated circuit. The control device of the present embodiment includes a liquid crystal panel driving part and an LED driving part. The liquid crystal panel driving part is a part that causes images to be displayed on the liquid crystal panel 10 by driving the liquid crystal panel 10, and corresponds to a driver circuit such as a gate driver or a source driver. The LED driving part is a part for turning each LED element 23 on or off individually, and for changing the light emission intensity, and is made of a driver device that includes a switch or the like, for example. When the light-emitting element is a cold-cathode fluorescent tube (CCFL), the LED driving part acts as a CCFL driving part (or as a backlight driving part).

A plurality of the LED elements 23 of the present embodiment are arrayed so as to emit light to the light guide plate 22, and are made of a white LED, for example. In the example shown in FIG. 1, the LED elements 23 are arrayed on one side of the light guide plate 22, but without being limited thereto, the LED elements 23 can also be arrayed on two or more sides (three sides, for example) of the light guide plate 22. As described above, the LED elements 23 can also be used in a direct LED backlight configuration.

Preferred embodiments of the present invention have been described above, but such descriptions are not limitations, and various modifications are possible. For example, in the embodiment described above, one liquid crystal panel 10 is used to make an image display unit, but it is also possible to combine a plurality of liquid crystal panels 10 to make one image display unit (a multi-display). A liquid crystal display device 100 with such a plurality of combined liquid crystal panels 10 can also be used for large-screen digital signage (for a display device 100 inches or above, for example).

### INDUSTRIAL APPLICABILITY

According to the present invention, an array substrate for a liquid crystal panel and a liquid crystal panel that can suppress disconnection of source wiring lines can be provided.

### DESCRIPTION OF REFERENCE CHARACTERS

10 liquid crystal panel
11 array substrate (array substrate for liquid crystal panel)
12 color filter substrate
13 polarizing plate
20 backlight unit
21 optical sheet
22 light guide plate
23 light-emitting element (LED element)
25 wiring substrate
27 reflective sheet
28 backlight chassis
29 bezel
30 TFT element
31 semiconductor layer
   32d drain electrode
   32s source electrode
   33 gate wiring line
   34 source wiring line
   34a main body part of source wiring line
   34b metal film
   34m resist pattern
   35 auxiliary capacitance wiring line (Cs wiring line)
   35b narrow-width part of Cs wiring line
   35e outer edge of Cs wiring line
   35m resist pattern
   36 drain wiring line
   37 pixel electrode
   38 glass substrate
   39 insulating film
   40 intersection wiring portion
   41 first portion
   42 second portion
   44 different-level area
   45 intersection region
   46 corroded area
   47 intersection region
   48 adjacent region
   49 straight-line area
   51 row direction
   52 column region
   70 foreign object
   100 liquid crystal display device
   110 array substrate
   111 pixel electrode
   112 gate wiring line
   114 data wiring line
   115 pixel area
   120 color filter substrate
   130 liquid crystal layer
   150 transparent substrate
   210 array substrate
   1000 liquid crystal panel

1. An array substrate for a liquid crystal panel with pixels arranged in a matrix having rows and columns, comprising:
auxiliary capacitance wiring that extends in a row direction; and
source wiring that is located in an upper layer above the auxiliary capacitance wiring and that extends in a column direction,
wherein the source wiring located in the upper layer has an intersection wiring portion on an intersection region of the auxiliary capacitance wiring and the source wiring, and
wherein the intersection wiring portion includes:
a first portion that continues to a main body part of the source wiring and that extends in the row direction; and
a second portion that continues to the first portion and that extends in a direction different than the row direction.

2. The array substrate according to claim 1,
wherein the second portion of the source wiring extends in the column direction, and
wherein the intersection wiring portion includes:
the first portion;
the second portion that extends perpendicularly from the first portion; and
an additional first portion that extends perpendicularly from the second portion and that leads to the main body part.

3. The array substrate according to claim 2, wherein the first portion and the additional first portion extend in the row direction so as to cover each outer edge of the auxiliary capacitance wiring located in a lower layer.

4. The array substrate according to claim 2, wherein a width of the auxiliary capacitance wiring becomes narrower on the intersection region.

5. The array substrate according to claim 1, wherein a width of the source wiring on the main body part is the same size as a width of the second portion on the intersection wiring portion.

6. The array substrate according to claim 1, wherein the intersection wiring portion including the first portion and the second portion is formed on all intersection regions of the auxiliary capacitance wiring and the source wiring.

7. The array substrate according to claim 1,
wherein the intersection wiring portion includes:
the first portion that forks from the main body part of the source wiring;
the second portion that is connected to the forked first portion, and
an additional first portion that connects the second portion and the main body part.

8. The array substrate according to claim 7, wherein the forked first portion and the additional first portion respectively extend in the row direction.

9. The array substrate according to claim 7, wherein the second portion includes a portion that extends at an angle with respect to the column direction.

10. The array substrate according to claim 1, further comprising gate wiring that extends in the row direction,
wherein the source wiring is located in an upper layer above the gate wiring, and
wherein the source wiring located in the upper layer overlaps the gate wiring in a straight-line portion at an intersection region of the gate wiring and the source wiring.

11. The array substrate according to claim 1, further comprising thin film transistors respectively formed on the pixels arranged in a matrix,
wherein the thin film transistors each comprise:
a source electrode that extends from the source wiring; and
a drain electrode arranged opposing the source electrode,
wherein drain wiring that is to be connected to a pixel electrode extends from the drain electrode, and
wherein an end of the drain wiring is connected to the auxiliary capacitance wiring.

12. The array substrate according to claim 1, wherein the source wiring is made of copper.

13. A liquid crystal panel, comprising:
the array substrate according to claim 1;
a color filter substrate arranged opposing the array substrate; and
a liquid crystal layer arranged between the array substrate and the color filter substrate.

14. A liquid crystal display device, comprising:
the liquid crystal panel according to claim 13; and
a backlight unit that radiates light to the liquid crystal panel.
